(19) United States
(12) Patent Application Publication
(10) Pub. No.: US 2019/0081218 A1
(43) Pub. Date: Mar. 14, 2019

(54) METHODS FOR DISPENSING QUANTUM DOT MATERIALS

(71) Applicant: CORNING INCORPORATED, CORNING, NY (US)

(72) Inventors: DAVID FRANCIS Dawson-Elli, Dundee, NY (US); Felipe Miguel Joos, Addison, NY (US); Gregory William Keyes, Rochester, NY (US); James Edward McGinnis, Watkins Glen, NY (US)

(21) Appl. No.: 16/072,952

(22) PCT Filed: Jan. 27, 2017
(86) PCT No.: PCT/US2017/015305

§ 371 Date: Jul. 26, 2018

Related U.S. Application Data
(60) Provisional application No. 62/288,187, filed on Jan. 28, 2016.

(51) Int. Cl. H01L 33/50; H01L 33/56; H01L 33/00

(52) U.S. Cl. CPC H01L 33/502; H01L 33/56; H01L 2933/005; H01L 2933/0041; H01L 33/005

(57) ABSTRACT

A method of dispensing quantum dot containing material in a well, the method comprising dispensing quantum dot material in a well using an ink jet, wherein the ink jet is operated with an Ohnesorge (Oh) number between 0.1 and 1 and with a Weber number of between 4 and 50^{1.6}*Oh^{0.4}. Other methods include dispensing quantum dot containing material in a well, the method comprising dispensing quantum dot material in a well using an ink jet, immobilizing the dispensed quantum dot material by drying or curing, repeating these steps an integer N number of times until a predetermined thickness is obtained.

### CROSS-REFERENCE TO RELATED APPLICATIONS

This application claims the benefit of priority under 35 U.S.C. § 119 of U.S. Provisional Application Ser. No. 62/288,187 filed on Jan. 28, 2016, the content of which is relied upon and incorporated herein by reference in its entirety.

### FIELD OF THE DISCLOSURE

The disclosure relates generally to sealed devices, and more particularly to sealed devices comprising quantum dot materials, as well as methods of dispensing such quantum dot materials.

### BACKGROUND

Sealed glass packages and casings are increasingly popular for application to electronics and other devices that may benefit from a hermetic environment for sustained operation. Exemplary devices that may benefit from hermetic packaging include televisions, sensors, optical devices, organic light emitting diode (OLED) displays, 3D inkjet printers, laser printers, solid-state lighting sources, and photovoltaic structures. For instance, displays comprising OLEDs or quantum dots (QDs) may call for sealed hermetic packages to prevent the possible decomposition of these materials at atmospheric conditions.

These packages conventionally include a well or plate of wells containing color converting material such as quantum dots. Conventionally, filling of wells and/or well plates is performed by dispensing the material through a needle as a stream or by depositing a number of large drops (for example, about 0.3 microliter, pL) by a mechanical valve activated pneumatically or using a piezoelectric stack. Several problems occur when dispensing by these methods. First, when dispensing through a needle, material being dispensed tends to stay on the tip of the needle, and therefore the total amount of material being dispensed varies by the amount that remains at the needle tip which can be a significant portion of the total dispensed material (in the foregoing example, typically about 5% of the total 3 μL). This variability is in addition to that provided by the delivery pump. Thus, there is a need to provide a more efficient and effective method of dispensing quantum dot materials into a well or cavity for a sealed device.

### SUMMARY

The disclosure relates, in various embodiments, to a method of dispensing quantum dot containing material in a well, the method comprising dispensing quantum dot material in a well using an ink jet, wherein the ink jet is operated with an Ohnesorge (Oh) number between 0.1 and 1 and with a Weber number of between 4 and 50^{1.6}*Oh^{0.4}. In some embodiments, the method may further comprise the step of immobilizing the dispensed quantum dot material by drying or curing. In other embodiments, the quantum dot material may further comprise a plurality of quantum dots contained in a resin. In some embodiments, the quantum dot material may include at least one quantum dot selected from the group consisting of ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, and combinations thereof. In further embodiments, the method may further comprise the step of roughening or providing striations to a surface of the dispensed quantum dot material.

In additional embodiments, a method of dispensing quantum dot containing material in a well is provided, the method comprising dispensing quantum dot material in a well using an ink jet, immobilizing the dispensed quantum dot material by drying or curing, and repeating these an integer N number of times until a predetermined thickness is obtained. In some embodiments, the ink jet may be operated with an Ohnesorge (Oh) number between 0.1 and 1 and with a Weber number of between 4 and 50^{1.6}*Oh^{0.4}. The integer number N may be greater than 1. In some embodiments, the quantum dot material may include at least one quantum dot selected from the group consisting of ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, and combinations thereof. In further embodiments, the method may further comprise the step of roughening or providing striations to a surface of the dispensed quantum dot material.

In further embodiments, a method of making a sealed device is provided comprising providing a first substrate containing an array of wells, dispensing quantum dot containing material in one or more wells of the array, hermetically sealing one or more wells in the array, and separating one or more wells from the array to form a sealed device. In some embodiments, the step of providing a first substrate containing an array of wells may further comprise the step of etching the first substrate to form the array of wells. In other embodiments, the step of dispensing quantum dot containing material may further comprise dispensing quantum dot material in a well using an ink jet, immobilizing the dispensed quantum dot material by drying or curing, and repeating these steps an integer N number of times (e.g., >or equal to 1) until a predetermined thickness is obtained. In further embodiments, the ink jet may be operated with an Ohnesorge (Oh) number between 0.1 and 1 and with a Weber number of between 4 and 50^{1.6}*Oh^{0.4}. In some embodiments, the step of hermetically sealing may further comprise bringing a first surface of a second substrate into contact with a second surface of the first substrate to form a sealing interface, and directing a laser beam operating at a predetermined wavelength onto the sealing interface to form a seal between the first and second substrates. In some embodiments, the quantum dot material may include at least one quantum dot selected from the group consisting of ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, and combinations thereof. In some embodiments, the first, second, or both first and second substrates can comprise a glass chosen from aluminosilicate, alkali-aluminosilicate, borosilicate, alkali-borosilicate, alum inoborosilicate, and alkali-aluminoborosilicate glasses. In further embodiments, the method may further comprise placing the sealed device over a third substrate, the third substrate comprising a third surface and having at least one cavity containing at least one LED component, and sealing the sealed device to the third substrate to form another seal extending around the at least one cavity. In additional embodiments, the method may comprise the step of providing one or more films to filter predetermined wavelengths of light, the one or more films comprising alternating films of high refractive index material and low refractive index material.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and, together with the description, serve to explain the principles and operations of the disclosure.

### BRIEF DESCRIPTION OF THE DRAWINGS

The following detailed description can be further understood when read in conjunction with the following drawings in which, where possible, like numerals are used to refer to like elements, and:

FIG. 1 illustrates a cross-sectional view of a quantum dot film positioned adjacent a cavity comprising a light emitting diode (LED);

FIGS. 2A-C illustrate cross-sectional views of sealed devices according to certain embodiments of the disclosure;

FIG. 3 is an illustration of some embodiments;

FIG. 4 is a map of an operating window for an exemplary inkjet process;

FIG. 5 is an image of a pattern dispensed in a well; and

FIG. 6 is a profile of a UV-cured resin thickness across three wells that experienced different deposition and curing treatments.

### DETAILED DESCRIPTION

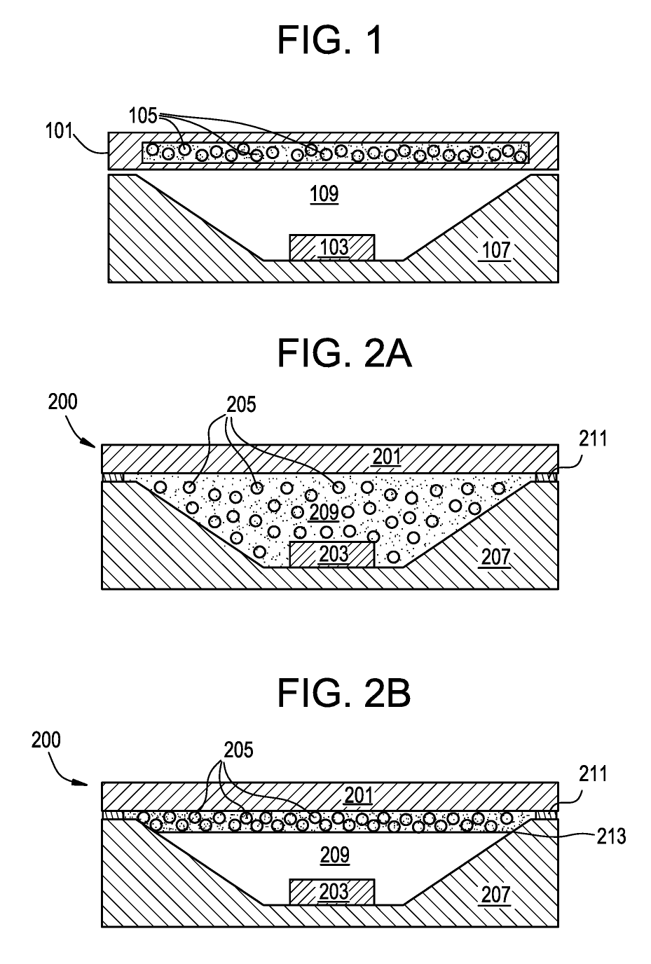

Disclosed herein are sealed devices comprising at least two substrates chosen from glass, glass-ceramic, and/or ceramic substrates. Exemplary sealed devices can include, for example, sealed devices encapsulating quantum dots, LEDs, laser diodes (LDs), and other light emitting structures. Display and optical devices comprising such sealed components are also disclosed herein. Displays such as televisions, computers, handheld devices, watches, and the like can comprise a backlight comprising quantum dots (QDs) as color converters. Exemplary optical devices can include but are not limited to sensors, including biosensors, watches and other devices configured to contain embodiments described herein. In some embodiments, QDs can be packaged, for example, in a glass tube, capillary, or sheet, e.g., a quantum dot enhancement film (QDEF) or encapsulated device such as a chiplet. Such films or devices can be filled with quantum dots, such as green and red emitting quantum dots, and can be sealed at both ends and/or around the periphery of the film or device. Due to the temperature sensitivity of QDs, backlights using quantum dot material avoid direct contact between the quantum dot material and the light source, e.g., LED. Thus, as shown in FIG. 1, a sealed device 101, comprising a plurality of QDs or QD containing material 105, is often incorporated into the backlight stack as a separate component, e.g., placed in proximity to the LED 103, but kept at a sufficient distance to prevent the harsh conditions (e.g., temperatures up to about 140° C. and luminous flux up to about 100 W/cm²) from damaging the QDs or QD containing material 105. For example, the sealed device 101 can be placed in proximity to a first substrate 107 comprising one or more cavities 109 comprising an LED 103. In some embodiments the sealed device 101 may include an upper substrate hermetically sealed to a lower substrate, both of which form an enclosure containing the QDs or QD containing material 105. This package or chiplet may then be sealed to the underlying first substrate 107. While not shown, such an embodiment may also be situated in the walls of the well formed in the first substrate 107 which contains the LED 103. In additional embodiments, one or more lenses (not shown), may be provided on a side of the chiplet or sealed device 101 opposite the LED 103.

The following general description is intended to provide an overview of exemplary quantum dot devices and methods for manufacturing the same, and various embodiments will be more specifically discussed throughout the disclosure with reference to the non-limiting examples, these embodiments being interchangeable with one another within the context of the disclosure. Reference will be made throughout the disclosure to a “first” substrate, a “glass” substrate, or a “first glass” substrate, these labels being used interchangeably to refer to the same substrates. Similarly, reference will be made throughout to a “second” substrate, an “inorganic” substrate, a “doped inorganic” substrate, or a “second inorganic” substrate, these labels being used interchangeably to refer to the same substrates.

### Devices

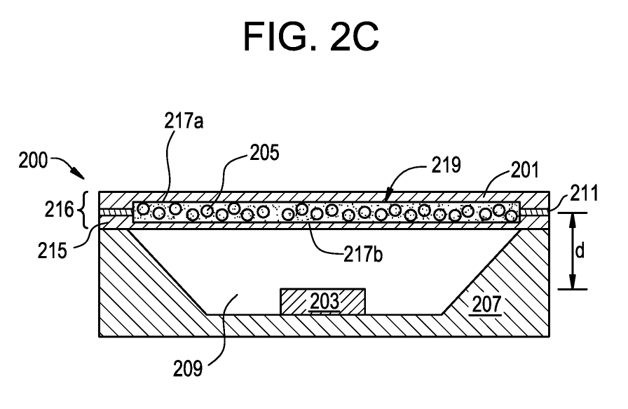

Cross-sectional views of two non-limiting embodiments of a sealed device 200 are illustrated in FIGS. 2A-B. The sealed device 200 comprises a first glass substrate 201 and a second inorganic substrate 207 comprising at least one cavity 209. The at least one cavity 209 can contain at least one quantum dot 205. The at least one cavity 209 can also contain at least one LED component 203. The first substrate 207 and second substrate 201 can be joined together by at least one seal 211, which seal can extend around the at least one cavity 209. Alternatively, the seal can extend around more than one cavity, such as a group of two or more cavities (not shown). In additional embodiments, one or more lenses (not shown), may be provided on a side of the first glass substrate 201 opposite the LED 203. The LED 203 may be any size in diameter or in length, for example, from about 100 micrometer (μm) to about 1 millimeter (mm), from about 200 μm to about 900 μm, from about 300 μm to about 800 μm, from about 400 μm to about 700 μm, from about 350 μm to about 400 μm and any sub-ranges therebetween. The LED 203 may also provide a high or low flux, for example, for high flux purposes the LED 203 may emit 20 W/cm² or more. For low flux purposes, the LED 203 may emit less than 20 W/cm².

In the non-limiting embodiment depicted in FIG. 2A, the at least one LED component 203 can be in direct contact with the at least one quantum dot 205. As used herein the term “contact” is intended to denote direct physical contact or interaction between two listed elements, e.g., the quantum dot and LED component are able to physically interact with one another within the cavity. In the non-limiting embodiment depicted in FIG. 2B, the at least one LED component 203 and the at least one quantum dot 205 may be present in the same cavity, but are separated, e.g., by a separation barrier or film 213. By way of comparison, quantum dots in separate sealed capillaries or sheets, e.g., a QDEF as shown in FIG. 1, are not able to directly interact with the LED and are not located in the cavity with the LED.

In the non-limiting embodiment depicted in FIG. 2C, a sealed device 200 may include at least one LED component 203, a first substrate 201, a second substrate 207, and a third substrate 215. The first substrate 201 and third substrate 215 may form an hermetically sealed package or device 216 which forms an enclosed and encapsulated region 219 or cavity containing the at least one quantum dot 205. In some embodiments the hermetically sealed package or device 216 will also include one or more films 217a, b such as, but not limited to, films that act as high pass filters and films that act as low pass filters or films that are provided to filter predetermined wavelengths of light. Methods for making such hermetically sealed packages or devices 216 and for dispensing quantum dot containing material 205 in the encapsulated region 219 are described in further detail below. In some embodiments, the at least one LED component 203 can be spaced apart from the at least one quantum dot 205 by a predetermined distance “d”. In some embodiments the predetermined distance can be less than or equal to about 100 μm. In other embodiments, the predetermined distance is between about 50 μm and about 2 mm, between about 75 μm and about 500 μm, between about 90 μm and about 300 μm, and all ranges and subranges therebetween. In some embodiments, the predetermined distance is measured from a top surface of the LED component 203 to a midline of the enclosed and encapsulated region 219 containing the at least one quantum dot 205. Of course, the predetermined distance may also be measured to any portion of the enclosed and encapsulated region 219 containing the at least one quantum dot 205 such as but not limited to an upper surface of the third substrate 215 facing the at least one quantum dot 205, a lower surface of the first substrate 201 facing the at least one quantum dot 205, or a surface formed by any one of the films or filters 217a, b which may be present in the hermetically sealed package or device 216. In some embodiments, exemplary films include a filter 217a that prevents blue light from an exemplary LED component 203 from escaping the device 216 in one direction and/or another filter 217b that prevents red light (or another light emitted by excited quantum dot material) from escaping the device 216 in a second direction. For example, in some embodiments, the device 200 may comprise one or more LED components 203 contained in a well or other enclosure formed by the second substrate 207 and/or other substrates. An hermetically sealed package or device 216 in close proximity (e.g., a predetermined distance as discussed above) to the one or more LED components may be fixed to or sealed to the second substrate 207 and may comprise a first substrate 201 hermetically sealed to a third substrate 215 that forms an encapsulated region 219 containing single wavelength quantum dot material 205 that emits light in an infrared wavelength, near-infrared wavelength, or in a predetermined spectrum (e.g., red) when excited by light emitted from the one or more LED components 203. The quantum dot material 205 can be spaced apart from the LED component 203 by a predetermined distance. In such an exemplary embodiment, a first filter 217a may be provided on the bottom (or top) surface of the first substrate 201 to filter blue light from emitting through the top surface of the device 200 and a second filter 217b may be provided on the top (or bottom) surface of the third substrate 215 to filter excited light from the quantum dot material from exiting the bottom surface of the third substrate 215. In additional embodiments, a filter 217c may be provided on the bottom surface of the second substrate 215 to filter blue light. These filters 217a, 217b, 217c, alone or in combination can in some embodiments include a plurality of thin film layers selected for their optical properties. In particular, exemplary filters 217a, 217b, 217c can be designed to have high transmission for blue wavelengths to allow a blue LED light to emerge from a light guide plate adjacent the device 200. Such filters can also possess a high reflection for red and green wavelengths to reduce backreflection of light from the quantum dot material 205 back into the light guide plate. One exemplary low pass filter 217a, 217b, 217c, includes a thin film stack made from multiple layers of high refractive index and low refractive index materials. In one embodiment, an exemplary filter comprises multiple alternating layers of a suitable high refractive index material and a suitable low refractive index material. Exemplary high refractive index materials include, but are not limited to, Nb₂O₅, Ta₂O₅, TiO₂, and compound oxides thereof. Exemplary low refractive index materials include, but are not limited to, SiO₂, ZrO₂, HfO₂, Bi₂O₃, La₂O₃, Al₂O₃, and compound oxides thereof.

Exemplary filter embodiments can be used between side lit or direct lit light guide plates and adjacent QD material, i.e., intermediate the QD material and light guide plates or as described above with reference to FIGS. 2B and 2C. For example, with continued reference to FIG. 2C, an exemplary filter 217c can improve the efficiency of directing light out of the package. In other embodiments, another location for the low pass filter can be on the cover glass (e.g., second substrate 215) such that the UV absorbing material is also an interference filter. Specifically, the material used as a high index material absorbs sufficient UV to enable the laser welding process described herein. These exemplary layers of material can be deposited by any number of thin film methods known in the art such as sputtering, plasma-enhanced chemical vapor deposition, and the like. The film or layer may be deposited directly onto the light guide plate or substrate or as a separate layer that is then attached by an optically clear adhesive. It was discovered that embodiments described herein having such filters (1) resulted in a higher forward light output, increasing overall brightness of the device 200 or light guide plate, (2) improved quantum dot conversion efficiency, enabling use of less quantum dot material, and (3) could rely on conventional thin film processing technology for ease of manufacture.

The first substrate 201, second substrate 207 and/or third substrate 215 can, in some embodiments, be chosen from glass substrates and may comprise any glass known in the art for use in display and other electronic devices. Suitable glasses can include, but are not limited to, aluminosilicate, alkali-aluminosilicate, borosilicate, alkali-borosilicate, aluminoborosilicate, alkali-aluminoborosilicate, and other suitable glasses. These substrates may, in various embodiments, be chemically strengthened and/or thermally tempered. Non-limiting examples of suitable commercially available substrates include EAGLE XG®, Lotus™, Iris™ Willow®, and Gorilla® glasses from Corning Incorporated, to name a few. Glasses that have been chemically strengthened by ion exchange may be suitable as substrates according to some non-limiting embodiments.

According to various embodiments, the first, second, and/or third glass substrates 201, 207, 215 may have a compressive stress greater than about 100 MPa and a depth of layer of compressive stress (DOL) greater than about 10 micrometers. In further embodiments, the first, second and/or third glass substrate may have a compressive stress greater than about 500 megaPascals (MPa) and a depth of compressive layer (DOL) greater than about 20 micrometers, or a compressive stress greater than about 700 MPa and a DOL greater than about 40 micrometers. In non-limiting embodiments, the first, second and/or third glass substrate can have a thickness of less than or equal to about 3 mm, for example, ranging from about 0.1 mm to about 2.5 mm, from about 0.3 mm to about 2 mm, from about 0.5 mm to about 1.5 mm, or from about 0.7 mm to about 1 mm, including all ranges and subranges therebetween.

The first, second and/or third glass substrates can, in various embodiments, be transparent or substantially transparent. As used herein, the term “transparent” is intended to denote that the substrate, at a thickness of approximately 1 mm, has a light transmission greater than about 80% in the visible region of the spectrum (e.g., 400-700 nm). For instance, an exemplary transparent substrate may have greater than about 85% transmittance in the visible light range, such as greater than about 90%, or greater than about 95%, including all ranges and subranges therebetween. In certain embodiments, an exemplary glass substrate may have a transmittance equal to or greater than about 50% in the ultraviolet (UV) region (200-400 nanometer, nm), such as equal to or greater than about 55%, equal to or greater than about 60%, equal to or greater than about 65%, equal to or greater than about 70%, equal to or greater than about 75%, equal to or greater than about 80%, equal to or greater than about 85%, equal to or greater than about 90%, equal to or greater than about 95%, or equal to or greater than about 99% transmittance, including all ranges and subranges therebetween.

According to various embodiments, the second substrate 207 can be chosen from inorganic substrates, such as inorganic substrates having a thermal conductivity greater than that of glass. For example, suitable inorganic substrates may include those with a relatively high thermal conductivity, such as equal to or greater than about 2.5 W/m-K (e.g., equal to or greater than about 2.6, 3, 5, 7.5, 10, 15, 20, 25, 30, 40, 50, 60, 70, 80, 90, or 100 W/m-K), for instance, ranging from about 2.5 W/m-K to about 100 W/m-K, including all ranges and subranges therebetween. In some embodiments, the thermal conductivity of the inorganic substrate can be equal to or greater than 100 W/m-K, such as ranging from about 100 W/m-K to about 300 W/m-K (e.g., equal to or greater than about 100, 110, 120, 130, 140, 150, 160, 170, 180, 190, 200, 210, 220, 230, 240, 250, 260, 270, 280, 290, or 300 W/m-K), including all ranges and subranges therebetween.

According to various embodiments, the inorganic substrate can comprise a ceramic substrate, which can include ceramic or glass-ceramic substrates. In a non-limiting embodiment, the second substrate 207 can comprise aluminum nitride, aluminum oxide, beryllium oxide, boron nitride, or silicon carbide, to name a few. The thickness of the inorganic substrate can range, in certain embodiments, from about 0.1 mm to about 3 mm, such as from about 0.2 mm to about 2.5 mm, from about 0.3 mm to about 2 mm, from about 0.4 mm to about 1.5 mm, from about 0.5 mm to about 1 mm, from about 0.6 mm to about 0.9 mm, or from about 0.7 mm to about 0.8 mm, including all ranges and subranges therebetween. In additional embodiments, the inorganic substrate may have little or no absorption at a given laser operating wavelength, e.g., at UV wavelengths (200-400 nm), or at visible wavelengths (400-700 nm). For instance, the second inorganic substrate may absorb less than about 10% at the laser's operating wavelength, such as equal to or less than about 5%, equal to or less than about 3%, equal to or less than about 2%, or equal to or less than about 1% absorption, e.g., from about 1% to about 10%. At visible wavelengths the inorganic substrate may, in some embodiments, be transparent or scattering.

In still further embodiments, any one or several of the first, second and third substrates may be doped with at least one dopant capable of absorbing light at a predetermined wavelength, e.g., at the predetermined operating wavelength of a laser. Dopants can include, for example, ZnO, SnO, SnO₂, TiO₂, and the like. In some embodiments, the dopant can be chosen from compounds absorbing at UV wavelengths (200-400 nm). The dopant can be incorporated into the inorganic substrates in an amount sufficient to induce absorption of the inorganic substrate at the predetermined wavelength. For instance, the dopant can be incorporated into the inorganic substrate at a concentration equal to or greater than about 0.05 weight percent (wt %) (500 parts per million, ppm), for example, ranging from about 500 ppm to about 10⁶ ppm. In some embodiments, the dopant concentration can be equal to or greater than about 0.5 wt %, equal to or greater than about 1 wt %, equal to or greater than about 2 wt %, equal to or greater than about 3 wt %, equal to or greater than about 4 wt %, equal to or greater than about 5 wt %, equal to or greater than about 6 wt %, equal to or greater than about 7 wt %, equal to or greater than about 8 wt %, equal to or greater than about 9 wt %, or equal to or greater than about 10 wt %, including all ranges and subranges therebetween. According to additional embodiments, the dopant may have a concentration greater than about 10 wt %, e.g., about 20 wt %, 30 wt %, 40 wt %, 50 wt %, 60 wt %, 70 wt %, 80 wt %, or 90 wt %, including all ranges and subranges therebetween. In further embodiments, the doped inorganic substrate may comprise about 100% dopant, e.g., in the case of a ZnO ceramic substrate.

According to various embodiments, the first, second and/or third substrates may be chosen such that the coefficients of thermal expansion (CTEs) of the substrates are substantially similar. For example, the CTE of the third or second substrate can be within about 50% of the CTE of the first substrate, such as within about 40%, within about 30%, within about 20%, within about 15%, within about 10%, or within about 5% of the CTE of the first substrate. By way of a non-limiting example, the CTE of the first glass substrate (at a temperature ranging from about 25-400° C.) can range from about 30×10⁻⁷/° C. to about 90×10⁻⁷/° C., such as from about 40×10⁻⁷/° C. to about 80×10⁻⁷/° C., or from about 50×10⁻⁷/° C. to about 60×10⁻⁷/° C. (such as about 30, 35, 40, 45, 50, 55, 60, 65, 70, 75, 80, 85, or 90×10⁻⁷/° C.), including all ranges and subranges therebetween. According to non-limiting embodiments, the glass substrates can be Corning® Gorilla® glass having a CTE ranging from about 75 to about 85×10⁻⁷/° C., or Corning® EAGLE XG®, Lotus^{TM}, or Willow® glasses having a CTE ranging from about 30 to about 50×10⁻⁷/° C. The second substrate can comprise an inorganic, e.g., ceramic or glass-ceramic substrate, having a CTE (at a temperature ranging from about 25-400° C.) ranging from about 20×10⁻⁷/° C. to about 100×10⁻⁷/° C., such as from about 30×10⁻⁷/° C. to about 80×10⁻⁷/° C., from about 40×10⁻⁷/° C. to about 70×10⁻⁷/° C., or from about 50 x 10⁻⁷/° C. to about 60×10⁻⁷/° C. (such as about 20, 25, 30, 35, 40, 45, 50, 55, 60, 65, 70, 75, 80, 85, 90, 95, or 100×10⁻⁷/° C.), including all ranges and subranges therebetween.

While FIGS. 1 and 2A-C depict the at least one cavity 109, 209 as having a trapezoidal cross-section, it is to be understood that the cavities can have any given shape or size, as desired for a given application. For example, the cavities can have a square, circular, rectangular, semi-circular, or semi-elliptical cross-section, or an irregular cross-section, to name a few. It is also possible for the surface of the first substrate 201 or third substrate 215 to comprise at least one cavity 209 (see, e.g., FIG. 2C), or for both the first or third and second substrates to comprise cavities. Alternatively, or additionally, cavities in the first or second substrates can be filled with a material that is transparent at one or both of visible wavelengths or LED operating wavelengths.

Moreover, while FIGS. 2A-B depict a sealed device comprising a single cavity 209, sealed devices comprising a plurality or array of cavities are also intended to fall within the scope of the disclosure. For example, the sealed device can comprise any number of cavities 209, which cavities can be arranged and/or spaced apart in any desired fashion including regular and irregular patterns. Furthermore, while the single cavity 209 in FIGS. 2A-B comprises both quantum dots and an LED component, it is to be understood that this depiction is not limiting. Embodiments in which one or more cavities 209 do not comprise quantum dots and/or LED components are also envisioned (see, e.g., FIG. 2C). Embodiments in which one or more cavities comprise a plurality of LED components and/or quantum dots are also envisioned. Moreover, it is not required that each cavity comprise the same number or amount of quantum dots and/or LED components, it being possible for this amount to vary from cavity to cavity and for some cavities to comprise no quantum dots and/or LED components.

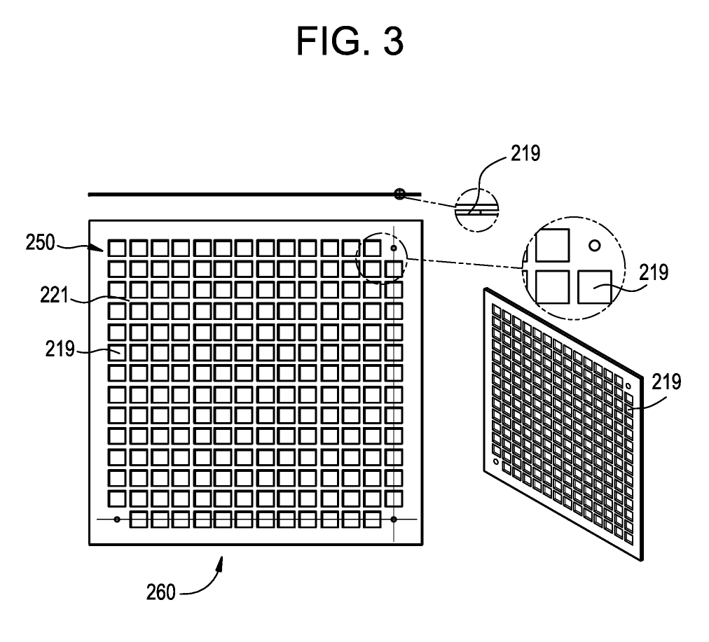

The at least one cavity 209 can have any given depth, which can be chosen as appropriate, e.g., for the type and/or shape and/or amount of the item (e.g., QD, LED, and/or LD) to be encapsulated in the cavity. By way of a non-limiting embodiment, the at least one cavity 209 can extend into the first and/or second substrates to a depth of equal to or less than about 1 mm, such as equal to or less than about 0.5 mm, equal to or less than about 0.4 mm, equal to or less than about 0.3 mm, equal to or less than about 0.2 mm, equal to or less than about 0.1 mm, equal to or less than about 0.05 mm, equal to or less than about 0.02 mm, or equal to or less than about 0.01 mm, including all ranges and subranges therebetween, such as ranging from about 0.01 mm to about 1 mm. It is also envisioned that an array of cavities can be used, each cavity having the same or a different depth, the same or a different shape, and/or the same or a different size, as compared to the other cavities in the array. With continued reference to FIG. 2C, the encapsulated region 219 can have any suitable dimension (length, width, and height). For example, the region 219 or well can be substantially square in geometry and contain any width or length, e.g., 5 mm by 5 mm (see, e.g., FIG. 3), 2 mm by 2 mm, 1 mm by 1 mm, 0.5 mm by 0.5 mm, equal to or less than 0.5 mm by 0.5 mm, or equal to or greater than 5 mm by 5 mm, and all subranges therebetween. The region 219 can also include dissimilar lengths and widths, e.g., 1 mm by 5 mm, 0.5 mm by 1 mm, etc. Exemplary region 219 or well heights including equal to or less than about 0.1 mm, between about 0.1 mm and about 0.2 mm, between about 0.1 mm and about 0.5 mm, between about 0.2 mm and about 0.3 mm, equal to or greater than about 0.5 mm, and all subranges therebetween.

Quantum dots or quantum dot containing material can have varying shapes and/or sizes depending on the desired wavelength of emitted light. For example, the frequency of emitted light may increase as the size of the quantum dot decreases, e.g., the color of the emitted light can shift from red to blue as the size of the quantum dot decreases. When irradiated with blue, UV, or near-UV light, a quantum dot may convert the light into longer red, yellow, green, or blue wavelengths. According to various embodiments, the quantum dot can be chosen from red and green quantum dots, emitting in the red and green wavelengths when irradiated with blue, UV, or near-UV light. For instance, the LED component can emit blue light (approximately 450-490 nm), UV light (approximately 200-400 nm), or near-UV light (approximately 300-450 nm).

Additionally, it is possible that the at least one cavity can comprise the same or different types of quantum dots, e.g., quantum dots emitting different wavelengths. For example, in some embodiments, a cavity can comprise quantum dots emitting both green and red wavelengths, to produce a red-green-blue (RGB) spectrum in the cavity. However, according to other embodiments, it is possible for an individual cavity to comprise only quantum dots emitting the same wavelength, such as a cavity comprising only green quantum dots or a cavity comprising only red quantum dots. For instance, the sealed device can comprise an array of cavities, in which approximately one-third of the cavities may be filled with green quantum dots and approximately one-third of the cavities may be filled with red quantum dots, while approximately one-third of the cavities may remain empty (so as to emit blue light). Using such a configuration, the entire array can produce the RGB spectrum, while also providing dynamic dimming for each individual color.

Of course, it is to be understood that cavities containing any type, color, or amount of quantum dots in any ratio are possible and envisioned as falling within the scope of the disclosure. It is within the ability of one skilled in the art to choose the configuration of the cavity or cavities and the types and amounts of quantum dots to place in each cavity to achieve a desired effect. Moreover, although the devices herein are discussed in terms of red and green quantum dots for display devices, it is to be understood that any type of quantum dot can be used, which can emit any wavelength of light including, but not limited to, red, orange, yellow, green, blue, or any other color in the visible spectrum (e.g., 400-700 nm).

Exemplary quantum dots can have various shapes. Examples of the shape of a quantum dot include, but are not limited to, sphere, rod, disk, tetrapod, other shapes, and/or mixtures thereof. Exemplary quantum dots may also be contained in a polymer resin such as, but not limited to, acrylate or another suitable polymer or monomer. Such exemplary resins may also include suitable scattering particles including, but not limited to, TiO₂ or the like.

In certain embodiments, quantum dots comprise inorganic semiconductor material that permits the combination of the soluble nature and processability of polymers with the high efficiency and stability of inorganic semiconductors. Inorganic semiconductor quantum dots are typically more stable in the presence of water vapor and oxygen than their organic semiconductor counterparts. As discussed above, because of their quantum-confined emissive properties, their luminescence can be extremely narrow-band and can yield highly saturated color emission, characterized by a single Gaussian spectrum. Because the nanocrystal diameter controls the quantum dot optical band gap, fine tuning of absorption and emission wavelengths can be achieved through synthesis and structure change.

In certain embodiments, inorganic semiconductor nanocrystal quantum dots comprise Group IV elements, Group II-VI compounds, Group II-V compounds, Group III-VI compounds, Group III-V compounds, Group IV-VI compounds, Group I-III-VI compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TIN, TIP, TIAs, TISb, PbO, PbS, PbSe, PbTe, alloys thereof, and/or mixtures thereof, including ternary and quaternary alloys and/or mixtures.

In certain embodiments a quantum dot can include a shell over at least a portion of a surface of the quantum dot. This structure is referred to as a core-shell structure. The shell can comprise an inorganic material, more preferably an inorganic semiconductor material. An inorganic shell can passivate surface electronic states to a far greater extent than organic capping groups. Examples of inorganic semiconductor materials for use in a shell include, but are not limited to, Group IV elements, Group II-VI compounds, Group II-V compounds, Group III-VI compounds, Group III-V compounds, Group IV-VI compounds, Group compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

In some embodiments, quantum dot materials can include II-VI semiconductors, including CdSe, CdS, and CdTe, and can be made to emit across the entire visible spectrum with narrow size distributions and high emission quantum efficiencies. For example, roughly 2 nm diameter CdSe quantum dots emit in the blue wavelengths while 8 nm diameter particles emit in the red wavelengths. Changing the quantum dot composition by substituting other semiconductor materials with a different band gap into the synthesis alters the region of the electromagnetic spectrum in which the quantum dot emission can be tuned. In other embodiments, the quantum dot materials are cadmium-free. Examples of cadmium-free quantum dot materials include InP and InₓGaₓ₋₁P. In an example of one approach for preparing InₓGaₓ₋₁P, InP can be doped with a small amount of Ga to shift the band gap to higher energies in order to access wavelengths slightly bluer than yellow/green wavelengths. In an example of another approach for preparing this ternary material, GaP can be doped with In to access wavelengths redder than deep blue wavelengths. InP has a direct bulk band gap of 1.27 eV, which can be tuned beyond 2 eV with Ga doping. Quantum dot materials comprising InP alone can provide tunable emission from yellow/green wavelengths to deep red wavelengths; the addition of a small amount of Ga to InP can facilitate tuning the emission down into the deep green/aqua green wavelengths. Quantum dot materials comprising InₓGaₓ₋₁P (0<x<1) can provide light emission that is tunable over at least a large portion of, if not the entire, visible wavelength spectrum. InP/ZnSeS core-shell quantum dots can be tuned from deep red wavelengths to yellow wavelengths with efficiencies as high as 70%. For creation of high CRI white QD-LED emitters, InP/ZnSeS can be utilized to address the red wavelengths to yellow/green wavelength portion of the visible wavelengths spectrum and InₓGaₓ₋₁P will provide deep green wavelengths to aqua-green wavelengths emission.

In some embodiments (e.g., see FIGS. 1, 2A, 2B and/or 2C), the quantum dot materials can provide a tunable emission in a predetermined spectrum. For example, exemplary quantum dot materials may be selected such that emission therefrom is only in a single wavelengths spectrum, i.e., single wavelength quantum dot material, such as but not limited to the red wavelengths spectrum, e.g., from about 620 nm to about 750 nm. Of course, exemplary single wavelength quantum dot materials may be selected such that other wavelength spectrums (e.g., violet 308-450 nm, blue 450-495 nm, green 495-570 nm, yellow 570-590 nm, and orange 590-620 nm) are emitted when excited by a nearby light source such as the at least one LED component 203. In other embodiments, the quantum dot materials can provide a tunable emission in another wavelength spectrum such as but not limited to the infrared wavelength spectrum, e.g., from about 700 nm to about 1 mm, or the ultraviolet wavelength spectrum, e.g., from about 10 nm to about 380 nm.

A first surface of the first substrate 201 and a second surface of the second substrate 207 can be joined by a seal or weld 211. The seal 211 can extend around the at least one cavity 209, thereby sealing the workpiece and or quantum dot material within the cavity. For example, as shown in FIGS. 2A-B the seal can encapsulate the at least one quantum dot 205 and the at least one LED component 203 in the same cavity. Similarly, a first surface of the first substrate 201 and a second surface of the third substrate 215 can be joined by a seal or weld 211. The seal 211 can extend around the at least one encapsulated region or well 219, thereby sealing the quantum dot material within the region 219. For example, as shown in FIG. 2C the seal 211 can encapsulate the at least one quantum dot 205 in the encapsulated region 219. In the case of multiple cavities, the seal 211 can extend around a single cavity, e.g., separating each cavity from the other cavities in the array to create one or more discrete sealed regions or pockets, or the seal can extend around more than one cavity, e.g., a group of two or more cavities, such as three, four, five, ten, or more cavities and so forth. It is also possible for the sealed device to comprise one or more cavities that may not be sealed, as desired, for example, in the case of a cavity devoid of an LED and/or quantum dots. Thus, it is to be understood that various cavities can be empty or otherwise free of quantum dots and/or LEDs, these empty cavities thus being sealed or unsealed as appropriate or desired. In some embodiments, the seal 211 can comprise a glass-to-glass seal, a glass-to-glass-ceramic seal, or a glass-to-ceramic seal as described in co-pending U.S. application Ser. Nos. 13/777,584; 13/891,291; 14/270,828; and 14/271,797, all of which are incorporated herein by reference in their entireties.

Materials forming the seal 211 can be chosen, for example, from glass compositions having an absorption of greater than about 10% at the predetermined laser operating wavelength and/or a relatively low glass transition temperature (T_{g}). According to various embodiments, the sealing materials can be chosen from borate glasses, phosphate glasses, tellurite glasses and chalcogenide glasses, for instance, tin phosphates, tin fluorophosphates, and tin fluoroborates.

In general, suitable sealing materials can include low T_{g} glasses and suitably reactive oxides of copper or tin. By way of non-limiting example, the sealing materials can comprise a glass with a T_{g} of less than or equal to about 400° C., such as less than or equal to about 350° C., about 300° C., about 250° C., or about 200° C., including all ranges and subranges therebetween, such as ranging from about 200° C. to about 400° C. Suitable sealing materials and methods are disclosed, for instance, in U.S. patent application Ser. Nos. 13/777,584; 13/891,291; 14/270,828; and 14/271,797, all of which are incorporated herein by reference in their entireties.

The thicknss of the seal 211 can vary depending on the application and, in certain embodiments, can range from about 0.1 micrometer to about 10 micrometers, such as equal to or less than about 5 micrometers, equal to or less than about 3 micrometers, equal to or less than about 2 micrometers, equal to or less than about 1 micrometers, equal to or less than about 0.5 micrometers, or equal to or less than about 0.2 micrometers, including all ranges and subranges therebetween. The seal 211 can have, in various embodiments, an absorption at the laser's operating wavelength (at room temperature) can be equal to or greater than about 10%, equal to or greater than about 15%, equal to or greater than about 20%, equal to or greater than about 25%, equal to or greater than about 30%, equal to or greater than about 35%, equal to or greater than about 40%, equal to or greater than about 45%, or equal to or greater than about 50%, including all ranges and subranges therebetween, such as from about 10% to about 50%. For example, the sealing materials can be absorbing at UV wavelengths (200-400 nm), e.g., having an absorption greater than about 10%. In some embodiments, the sealing materials can be transparent or substantially transparent to visible light, e.g., having a transmission equal to or greater than about 80% in the visible region of the spectrum (e.g., 400-700 nm).

In some embodiments, the seal 211 can comprise a continuous sheet or layer between the first, second, and/or third substrates 201, 207, 215. For instance, the sealing material can be overlaid onto the first surface or second surface of the respective substrates such that a sealing layer covers the at least one cavity and/or encapsulating region. In such embodiments, the seal 211 may be substantially transparent at visible wavelengths and absorbing at UV wavelengths (or any other predetermined laser operating wavelength). Alternatively, the sealing material can be provided such that it forms a frame around the cavity and/or encapsulating region. The sealing material can be applied to the first substrate 201, second substrate 207, or third substrate 215 in any desired shape or pattern. In such embodiments, the seal 211 can be substantially transparent or absorbing at visible wavelengths and/or substantially transparent or absorbing at UV wavelengths (or any other predetermined laser operating wavelength). For example, the laser can be chosen to operate at any wavelength at which the sealing layer is absorbing and the first glass substrate is non-absorbing. Of course, the seal can have any shape as desired for a particular application depending, e.g., on the substrate and/or cavity shape.

The seal 211 between the first, second, and/or third substrates as depicted in FIGS. 2A-C can be formed through the use of a laser beam operating at a given wavelength and directed at the sealing material (or sealing interface) to form a seal or weld between the two substrates. Without wishing to be bound by theory, it is believed that absorption of light from the laser beam by the sealing material and induced transient absorption by the first, second and/or third substrates can cause localized heating (e.g., to a temperature close to the glass transition temperature T_{g} of the first substrate) and melting of the sealing material and/or glass substrate to form a bond between the two substrates. According to various embodiments, the seal or weld 211 can have a width ranging from about 10 micrometers to about 300 micrometers, such as from about 25 micrometers to about 250 micrometers, from about 50 micrometers to about 200 micrometers, or from about 100 micrometers to about 150 micrometers, including all ranges and subranges therebetween.

The first, second, and/or third substrates can, in various embodiments be sealed together as disclosed herein, to produce a seal or weld around the at least one cavity and/or encapsulated region. In certain embodiments, the seal or weld may be a hermetic seal, e.g., forming one or more air-tight and/or waterproof pockets in the device. For example, at least one cavity can be hermetically sealed such that the cavity or region is impervious or substantially impervious to water, moisture, air, and/or other contaminants. By way of non-limiting example, an hermetic seal can be configured to limit the transpiration (diffusion) of oxygen to less than about 10⁻² cm³/m²/day (e.g., less than about 10⁻³/cm³/m²/day), and limit transpiration of water to about 10⁻² g/m²/day (e.g., less than about 10⁻³, 10⁻⁴, 10⁻⁵, or 10⁻⁶ g/m²/day). In various embodiments, a hermetic seal can substantially prevent water, moisture, and/or air from contacting the components or quantum dot material protected by the hermetic seal.

According to certain aspects, the total thickness of the sealed device can be equal to or less than about 6 mm, such as equal to or less than about 5 mm, equal to or less than about 4 mm, equal to or less than about 3 mm, equal to or less than about 2 mm, equal to or less than about 1.5 mm, equal to or less than about 1 mm, or equal to or less than about 0.5 mm, including all ranges and subranges therebetween. For example, the thickness of the sealed device can range from about 0.3 mm to about 3 mm, such as from about 0.5 mm to about 2.5 mm, or from about 1 mm to about 2 mm, including all ranges and subranges therebetween.

The sealed devices disclosed herein may be used in various display devices or display components including, but not limited to backlights or backlit displays such as televisions, computer monitors, handheld devices, and the like, which can comprise various additional components. The sealed devices disclosed herein can also be used as illuminating devices, such as luminaires and solid state lighting applications. For example, a sealed device comprising quantum dots in contact with at least one LED die can be used for general illumination, e.g. mimicking the broadband output of the sun. Such lighting devices can comprise, for example, quantum dots of various sizes emitting at various wavelengths, such as wavelengths ranging from 400-700 nm.

### Methods

Disclosed herein are also methods for making sealed devices containing quantum dot materials.

With reference to FIGS. 1, 2C, and 3, the encapsulated regions or wells 219 can be arranged in two dimensional arrays 250 on a glass plate, generally referred to as a well plate 260. In some embodiments, the wells 219 can be formed by machining or other suitable mechanical processes. In further embodiments, an exemplary method for manufacturing the wells 219 includes chemically etching the array of wells into the plate 260. Once a specified amount of liquid or quantum dot containing material 205 is dispensed into each well in the array, the material 205 can be cured, e.g., UV-cured and paired to a flat cover glass (e.g., first substrate 201). After a sealing process (e.g., laser sealing) the wells 219 undergo a separation or dicing process. Thus, the material in each well 219 should be completely encapsulated so that the separation occurs at the center of each of the lands 221.

In some embodiments, valves can be used to dispense single drops, such as a pico-dot valve. In these embodiments, the quantum dot material can be pressurized in a delivery system whereby at the exit of the delivery system there is an orifice plugged by a plunger that is removed using a piezoelectric mechanism. The quantum dot material is thus ejected from the delivery system and impacts the floor of the well. The amount of quantum dot material delivered in this manner can depend on the pressure and time that the valve is open, and on the viscosity of the material being dispensed. The desired amount of quantum dot material is dispensed by adjusting the volume of each shot and the number of shots per well. When using such a method, attention should be paid to maintaining the quantum dot containing material in the well and minimizing creep of the same over the edge of the well onto the lands. To ensure full wetting of the floor of each well, the shots must be placed in a specific pattern which can be achieved by distributing the drops evenly along the well's floor in a spiral pattern. In such a process, the drops should not be too close to the walls of the well to avoid the quantum dot material creeping on the lands, and some drops may be needed near the center of the floor to ensure that the entire floor is wet. If, during the process, quantum dot material appears on the lands caused by small (satellite) drops being shed from the shot as the valve closes that does not follow the trajectory of the main body of the shot or by splashing once the shot hits the surface of the well, this can be corrected by increasing the viscosity of the quantum dot material (if possible) or adjusting pressure in the delivery line and the details in the way the plunger in the valve moves in and out of the orifice.

In these embodiments, another difficulty discovered was that the quantum dot material or film is sufficiently thick to be mobile enough that within seconds it adopts its hydrostatic shape, with the film pinned to the wall's edges where the well meets the plate's land. As the well is only partially filled, with the empty part being a significant fraction of the entire well volume, the quantum dot material's top interface becomes highly concave, with the film near the walls being exceedingly thick and at the center exceedingly thin. In such instances, it was discovered that a single jetting valve requires several seconds to dispense the right amount of quantum dot material per well, and that 100 mm square well-plates take a significant fraction of an hour to be filled in this way and UV-cured. Splashing and droplet generation limit the speed at which the shots are dispensed, so in some embodiments scaling up capacity to industrial methods using these valve-dispensing methods may require a plurality of valves and associated tooling.

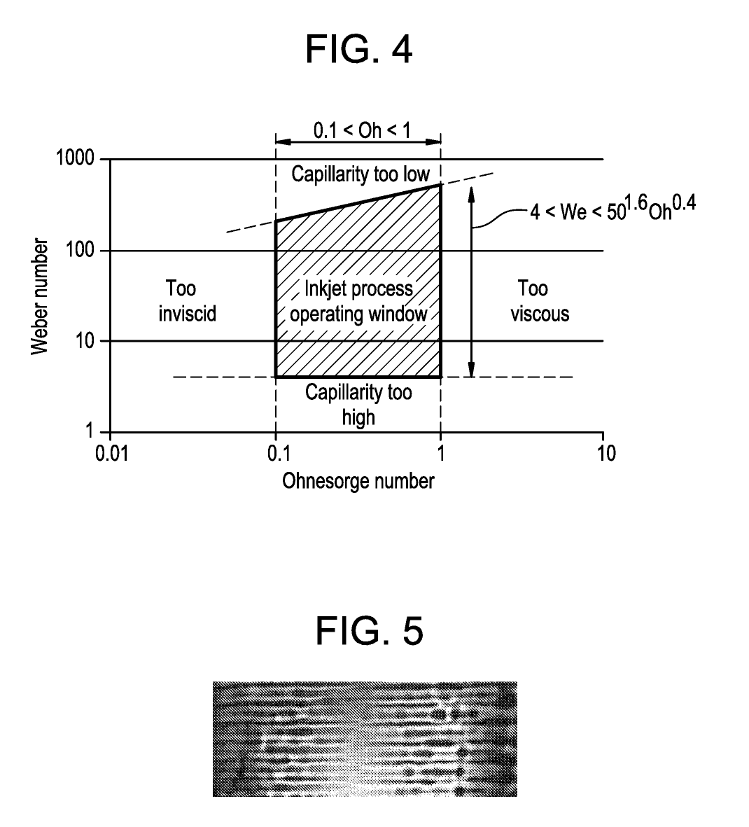

In preferable embodiments, the quantum dot containing material can be inkjetted into the wells. For a quantum dot containing material to be able to be properly dispensed using an inkjet method, it was determined that a number of conditions should be achieved. FIG. 4 is a map of an operating window for an exemplary inkjet process. With reference to FIG. 4, the axes represent two dimensionless numbers, named after Ohnesorge (Oh) and Weber (We). These are defined by physical and geometrical properties provided by the equations below:

$$Oh = \frac{μ}{\sqrt{σρ a}} and We = \frac{ρ {V}^{2} a}{σ} \qquad ( 1 )$$

where μ, ρ and σ represent, respectively, the liquid's viscosity, density and interfacial surface tension, a is a characteristic length (taken to be droplet diameter) and V represents the velocity of the droplet. For points outside the shaded window in FIG. 4, certain defects can occur. For example, to the left of the window, there is no control over the ejection or shape of the droplet as there is no viscous damping effect. Below the window drops will not eject from the nozzle because surface tension is too high. To the right of the window the drops don't eject because viscosity is too high. Above the window the drops tend to break up and splash because surface tension is too low. Thus, exemplary embodiments described herein provide a process for dispensing a matrix resin containing quantum into wells that resolves the following issues: (1) the total volume dispensed to each well has to be accurately controlled, (2) no liquid can be deposited on the plate other than in the well, (3) the thickness of the layer in the well must be uniform or patterned with striations or specific roughness, (4) the color set point is changed on the fly by operating four different inks simultaneously, and (5) the number of wells filled per day should be on an industrial level (e.g., >1 million/day). Thus, it was discovered that exemplary dispensing processes (e.g., inkjetting or the like) can be operated with an Ohnesorge (Oh) number between about 0.1 and about 1 and with a Weber number of between about 4 and about 50^{1.6}*Oh^{0.4}.

In some embodiments, an exemplary process includes applying a resin containing quantum dot material using an inkjet print head that is operated within an exemplary inkjet operating window (see FIG. 4) and on a sliding table that is precisely controlled to dispense the drops only in the wells whereby the resin is dispensed rapidly but in several passes. In some embodiments, the deposited resin (e.g., quantum dot containing material) is UV-cured between selected passes thus mitigating the outflow thereof. Embodiments of the present subject matter can dispense ink rapidly with precision, both in volume and in location, by using an inkjet printing head mounted on an accurate positioning table, with the print head facing down at a vacuum platen on which the well plate is mounted. In such embodiments, a vision system can be used to position the well plate accurately and may also be used to determine the position of the plate and there locate the wells in which the liquid will be dispensed using an inkjet printing method.

Some exemplary methods can employ a positioning table having a suitable translating mechanism or a conveyance mechanism that moves a substrate or well plate in a first linear direction(s) (i.e., a direction perpendicular to the rows(s) of nozzle orifices on a respective print head), and in a second direction(s) orthogonal to the first linear direction(s). Suitable print heads can be commercially available print heads, preferably as long or longer than the dimension of the well plate, and in some embodiments, a piezo-electrically actuated print head. In other embodiments, the print head can be a bank of smaller print heads which can cover the width of the entire well plate. Such exemplary print heads can be used to deposit one or more colors of quantum-dot material in single pass operations or simultaneously by, for example, banking two sets of print heads, one of each color. Motion of the print head over the well plate as well as the firing of the respective drops of quantum dot material can be controlled using a computer or processor. A delivery system can be used to supply the quantum dot containing material to the print head, which is maintained at a pressure sufficient to ensure proper firing of the jets. In certain embodiments, attributes (e.g., viscosity, size of quantum dots, size of scattering material, and the like) of the quantum dot material can be controlled to ensure proper dispensing function of the material within the inkjet process operating window (see FIG. 4). In embodiments where the well plate is wider than the print head (or bank of print heads), the positioning platform may require motion in a third direction orthogonal to both the first and second directions.

In further embodiments, the deposited or dispensed quantum dot material can be solidified by drying with infrared lamps or by curing with UV lamps or the like.

As noted above, embodiments of the subject matter and the functional operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer program products, i.e., one or more modules of computer program instructions encoded on a tangible program carrier for execution by, or to control the operation of, data processing apparatus. The tangible program carrier can be a computer readable medium. The computer readable medium can be a machine-readable storage device, a machine readable storage substrate, a memory device, or a combination of one or more of them.

The term “processor” or “controller” can encompass all apparatus, devices, and machines for processing data, including by way of example a programmable processor, a computer, or multiple processors or computers. The processor can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, or declarative or procedural languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more data memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices.

Computer readable media suitable for storing computer program instructions and data include all forms data memory including nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, input from the user can be received in any form, including acoustic, speech, or tactile input.

Embodiments of the subject matter described herein can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described herein, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet. The computing system can include clients and servers. A client and server are generally remote from each other and typically interact through a communication network. The relationship of client and server arises by virtue of computer programs running on the respective computers and having a client-server relationship to each other.

Experiments were conducted using the process described above. In some experiments, a Konica-Minolta KM1024 was used, which provides 360 dpi for droplet volume/maximum frequency combinations of 6 μL/30 kHz, 14 μL/12.8 kHz and 42 μL/ 7.6 kHz. Maximum flow rate qₙ from each nozzle can be represented by the following relationship:

qₙ=vf (2)

where v represents droplet volume and f represents frequency of ejection. For the KM1024 print head family, the highest flow rate achieved was performed by the combination 42 picoLiter/7.6 kHz. For example, a single pass would provide a layer of 42 picoLiter (μL) drops laid down at a separation of λ=1/360 dots per inch (dpi) (=70.6 μm) in two orthogonal directions. Thus, as a single layer of drops coalesces, the average thickness can be represented by the drops' volume divided by the area allotted to each in a two dimensional array. It follows that an average thickness δ of a layer of these drops, once coalesced, can be represented by the following relationship:

$$δ = \frac{v}{{λ}^{2}} \qquad ( 3 )$$

which was determined, in this non-limiting experiment, as 8.4 μm. Thus, if, for example, some embodiments need to dispense a layer that is d=120 μm thin on average, this could be done with d/δ=14.3 passes, i.e., in fifteen passes. Thus, these relationships described above can be used to provide a layer of quantum dot material in a well having any suitable thickness including from about 0.1 μm to about 200 μm, from about 1 μm to about 200 μm, from about 10 μm to about 150 μm, from about 50 μm to about 100 μm, and all ranges and subranges therebetween.

In embodiments where the length of the row of nozzles is less than the width of the working area of the respective well plate, the print head may raster, which can increase the dispensing time. For example, if the well plate has a working length L and width W, the time it will take to fill the wells to a desired thickness will depend on the average desired thickness of the layer and the length of the row of nozzles on the print head. If this length is equal to or greater than the width of the well plate, then all the wells in the plate can be filled at the same time. Assuming a total average thickness of liquid in the well of d=120 μm, each nozzle must fill a strip λ wide, L long, and d tall. Thus, for example, and assuming a length L=100 mm, the number N of drops that need to be ejected from each orifice can be represented as:

$$N = \frac{λ L δ}{v} \qquad ( 4 )$$

In the above experiment, the number of drops ejected by an orifice would be about 20,200. The minimum time T it takes to deliver all those drops depends on the frequency f using the relationship:

$$T = \frac{N}{f} \qquad ( 5 )$$

which would amount to a total of 2.7 seconds in the non-limiting experiment. The speed S at which the print head would have to translate depends on the drop spacing A and the frequency f using the following relationship:

S=λf (6)

whereby a speed of 0.53 m/s was calculated.

In additional embodiments, the physical properties of the quantum dot containing material or ink must also be defined within the confines of FIG. 4. For example, it was found that droplet speeds in successful inkjet printing experiments were in the range of 6 to 8 m/s. Assuming a liquid density near water (1 gm/mL) and a surface tension characteristic of solvents typically used (24 dyne/cm), it was found that if V=7 m/s and a=43 μm (the diameter of a 42 μL sphere), then We=88 which would be within the operating window. The viscosity of the quantum dot containing material or ink can then be selected by ensuring the Ohnesorge number is appropriate. For example, if Oh is approximately equal to 0.3, then for the numbers given, the target value of viscosity should be about 9.6 centiPoise (cP). It should be noted that these examples and experiments should not limit the scope of the claims appended herewith as the physical properties of the quantum dot containing material or ink can be within any number of ranges so long as the process window fits within the confines of FIG. 4, e.g., process operation having an Ohnesorge (Oh) number between 0.1 and 1 and with a Weber number of between 4 and 50^{1.6}*Oh^{0.4}. Thus, embodiments described herein can provide an inkjetting process for quantum dot material that minimizes splashing of drops onto the lands, minimizes formation of satellite droplets, minimizes creep flow of the material in the well through UV-curing thin layers of the deposited material in the wells, and provides an efficient, controlled, and repeatable dispensing process which leads to an accurate deposition of total volume in each well of an array of wells.

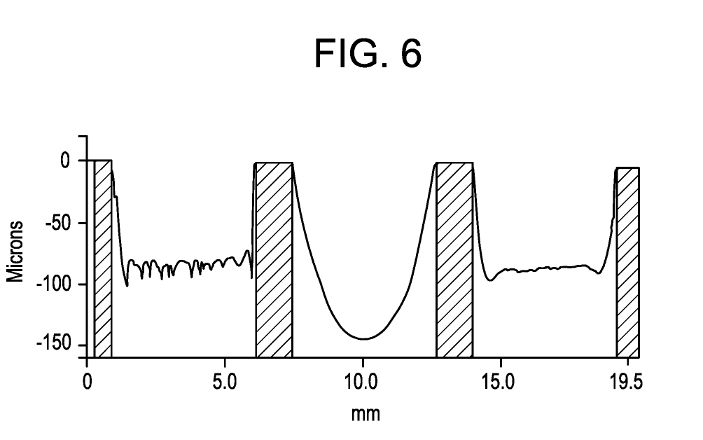

Aside from dispensing the quantum dot containing material into the wells, there is a need to immobilize the layer by drying or curing. In some embodiments, it may be beneficial to cure thin layers immediately after one or several passes. This step may be conducted an integer N number of times. In some embodiments N=1. In other embodiments N is greater than 1. This can enable single sided curing, where the UV light penetrates only to the thickness of the liquid film that needs curing. Such an exemplary process can reduce the flow of the film as it wicks along the walls and becomes nonuniform (e.g., concave, when looked at from above). In further embodiments, different roughnesses or even striations to the surface of the deposited material can be created if found convenient (see, e.g., FIG. 5 which is an image of a pattern provided on a dispensed quantum dot material in a well). FIG. 6 is a profile of a UV-cured resin thickness across three wells that experienced different deposition and curing treatments. With reference to FIG. 6, a profilometer scan was conducted across three different wells. The deposition and UV-cure procedure was different for each of these wells. For example, in the well represented by the right-hand side profilometer scan, the inkjetted ribbons were not allowed to coalesce by dispensing the liquid in ribbons and UV-curing very thin layers. In the well represented by the center profilometer scan, a hydrostatic profile is illustrated when curing was performed only after flow had completely ceased. Finally, in the well represented by the left-hand side profilometer scan, a film was applied using several cycles of deposition and UV-curing with a time between the deposition and curing to allow a leveling of any surface features on the dispensed quantum dot material. This can be achieved by printing isolated lines or individual drops or groups of drops that are allowed to coalesce in the wells and then promptly or instantaneously UV-curing them.

Exemplary embodiments and processes thus provide the ability to change a color set point of the quantum dot resin material “on the fly” by dispensing up to four separate materials, each material rich in one of the ingredients of the quantum dot resin material (e.g., red quantum dots, green quantum dots, scattering agents, matrix resin, and combinations thereof).

According to various embodiments, a sealing layer can optionally be applied to at least a portion of the glass substrate or at least a portion of the inorganic substrate prior to sealing. As discussed above, the first, second, and/or third substrates may comprise at least one cavity or encapsulating regions. Cavities can be provided in the first, second, or third substrates, e.g., by pressing, etching, molding, cutting, or any other suitable method. The sealing layer, if present, can be applied over any such cavity, or can be framed around the cavity. In some embodiments, at least one quantum dot and/or at least one LED component can be placed in the cavity. In alternative embodiments, at least one laser diode can be placed in the cavity. In further embodiments, a work piece can be placed in the cavity.

According to various embodiments, the substrate may be a doped inorganic substrate. Doping can be carried out, for instance, during formation of the inorganic substrate, e.g., at least one dopant or precursor thereof can be added to the batch materials used to form the inorganic substrate. Suitable dopants can include, for example, ZnO, SnO, SnO₂, TiO₂, and the like. Exemplary dopant concentrations may include, for instance, equal to or greater than about 0.05 wt % (e.g., greater than about 1, 2, 3, 4, 5, 6, 7, 8, 9, or 10 wt %, and so on).

The first surface and second surface can then be brought into contact, optionally with the sealing layer positioned therebetween, to form a sealing interface. The substrates thus contacted can be sealed, e.g., around at least one cavity. According to various non-limiting embodiments, sealing can be carried out by laser welding. For example, a laser can be directed at or on a sealing interface such that the sealing layer absorbs the laser energy and heats the interface to a temperature near the T_{g} of the glass substrate. Melting of the sealing layer and/or glass substrate can thus form a bond between the first and second substrates. Alternatively, a sealing layer may not be present and the second inorganic substrate may be doped such that it absorbs the laser energy and heats the interface to a temperature near the T_{g} of the glass substrate. In various embodiments, laser sealing can be carried out at temperatures at or near room temperature, such as from about 25° C. to about 50° C., or from about 30° C. to about 40° C., including all ranges and subranges therebetween. While heating at the sealing interface may cause a temperature increase exceeding these temperatures, such heating is localized at the sealing region, thus decreasing the risk of damage to any heat-sensitive work pieces to be encapsulated in the device.

The laser may be chosen from any suitable laser known in the art for glass substrate welding. For example, the laser may emit light at UV (from about 200 to about 400 nm), visible (from about 400 to about 700 nm), or infrared (from about 700 to about 1600 nm) wavelengths. According to various embodiments, the laser may operate at a predetermined wavelength ranging from about 300 nm to about 1600 nm, such as from about 350 nm to about 1400 nm, from about 400 nm to about 1000 nm, from about 450 nm to about 750 nm, from about 500 nm to about 700 nm, or from about 600 nm to about 650 nm, including all ranges and subranges therebetween. In certain embodiments, the laser may be a UV laser operating at about 355 nm, a visible light laser operating at about 532 nm, or a near-infrared laser operating at about 810 nm, or any other suitable NIR wavelength. According to additional embodiments, the laser operating wavelength may be chosen as any wavelength at which the first glass substrate is substantially transparent and the sealing layer and/or inorganic substrate is absorbing. Exemplary lasers include IR lasers, argon ion beam lasers, helium-cadmium lasers, and third-harmonic generating lasers, to name a few.

In certain embodiments, the laser beam can have an average power ranging from about 0.2 W to about 50 W, such as from about 0.5 W to about 40 W, from about 1 W to about 30 W, from about 2 W to about 25 W, from about 3 W to about 20 W, from about 4 W to about 15 W, from about 5 W to about 12 W, from about 6 W to about 10 W, or from about 7 W to about 8 W, including all ranges and subranges therebetween. The laser may operate at any frequency and may, in certain embodiments, operate in a pulsed, modulated (quasi-continuous), or continuous manner. In some embodiments, the laser may operate in burst mode, each burst comprising a plurality of individual pulses. In some non-limiting embodiments, the laser may have a repetition rate ranging from about 1 kHz to about 1 MHz, such as from about 5 kHz to about 900 kHz, from about 10 kHz to about 800 kHz, from about 20 kHz to about 700 kHz, from about 30 kHz to about 600 kHz, from about 40 kHz to about 500 kHz, from about 50 kHz to about 400 kHz, from about 60 kHz to about 300 kHz, from about 70 kHz to about 200 kHz, or from about 80 kHz to about 100 kHz, including all ranges and subranges therebetween.

According to various embodiments, the beam may be directed at and focused on the sealing interface, below the sealing interface, or above the sealing interface. The beam spot diameter on the interface may be less than about 1 mm in some non-limiting embodiments. For example, the beam spot diameter may be less than about 500 micrometers, such as equal to or less than about 400 micrometers, equal to or less than about 300 micrometers, or equal to or less than about 200 micrometers, equal to or less than about 100 micrometers, equal to or less than 50 micrometers, or equal to or less than 20 micrometers, including all ranges and subranges therebetween. In some embodiments, the beam spot diameter may range from about 10 micrometersto about 500 micrometers, such as from about 50 micrometersto about 250 micrometers, from about 75 micrometersto about 200 micrometers, or from about 100 micrometersto about 150 micrometers, including all ranges and subranges therebetween.

According to various embodiments, sealing the substrate can comprise scanning or translating a laser beam along the substrates (or the substrates can be translated relative to the laser) using any predetermined path to produce any pattern, such as a square, rectangular, circular, oval, or any other suitable pattern or shape, for example, to hermetically seal at least one cavity in the device. The translation speed at which the laser beam (or substrate) moves along the interface may vary by application and may depend, for example, upon the composition of the first and second substrates and/or the focal configuration and/or the laser power, frequency, and/or wavelength. In certain embodiments, the laser may have a translation speed ranging from about 1 mm/s to about 1000 mm/s, for example, from about 5 mm/s to about 750 mm/s, from about 10 mm/s to about 500 mm/s, or from about 50 mm/s to about 250 mm/s, such as equal to or greater than about 100 mm/s, equal to or greater than about 200 mm/s, equal to or greater than about 300 mm/s, equal to or greater than about 400 mm/s, equal to or greater than about 500 mm/s, or equal to or greater than about 600 mm/s, including all ranges and subranges therebetween.

According to various embodiments disclosed herein, the laser wavelength, pulse duration, repetition rate, average power, focusing conditions, and other relevant parameters may be varied so as to produce energy sufficient to weld the first and second substrates together by way of the sealing layer. It is within the ability of one skilled in the art to vary these parameters as necessary for a desired application. In various embodiments, the laser fluence (or intensity) is below the damage threshold of the first and/or second substrate, e.g., the laser operates under conditions intense enough to weld the substrates together, but not so intense as to damage the substrates. In certain embodiments, the laser beam may operate at a translation speed that is less than or equal to the product of the diameter of the laser beam at the sealing interface and the repetition rate of the laser beam.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a cavity” includes examples having one such “cavity” or two or more such “cavities” unless the context clearly indicates otherwise. Similarly, a “plurality” or an “array” is intended to denote two or more, such that an “array of cavities” or a “plurality of cavities” denotes two or more such cavities.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

All numerical values expressed herein are to be interpreted as including “about,” whether or not so stated, unless expressly indicated otherwise. It is further understood, however, that each numerical value recited is precisely contemplated as well, regardless of whether it is expressed as “about” that value. Thus, “a dimension less than 10 mm” and “a dimension less than about 10 mm” both include embodiments of “a dimension less than about 10 mm” as well as “a dimension less than 10 mm.”

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a method comprising A+B+C include embodiments where a method consists of A+B+C, and embodiments where a method consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

1. A method of dispensing quantum dot containing material in a well, the method comprising:
dispensing quantum dot material in a well using an ink jet,
wherein the ink jet is operated with an Ohnesorge (Oh) number between about 0.1 and about 1 and with a Weber number of between 4 and 50^{1.6}*Oh^{0.4}.

2. The method of claim 1, further comprising the step of immobilizing the dispensed quantum dot material by drying or curing.

3. The method of claim 1, wherein the quantum dot material further comprises a plurality of quantum dots contained in a resin.

4. The method of claim 3, wherein the quantum dot material includes at least one quantum dot selected from the group consisting of ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, and combinations thereof.

5. The method of claim 1, further comprising the step of roughening or providing striations to a surface of the dispensed quantum dot material.

6. A method of dispensing quantum dot containing material in a well, the method comprising:
(a) dispensing quantum dot material in a well using an ink jet;
(b) immobilizing the dispensed quantum dot material by drying or curing the dispensed quantum dot material; and
(c) repeating steps (a) and (b) an integer N number of times until a predetermined thickness of the quantum dot material is obtained.

7. The method of claim 6, wherein the ink jet is operated with an Ohnesorge (Oh) number between about 0.1 and about 1 and with a Weber number of between about 4 and about 50^{1.6}*Oh^{0.4}.

8. The method of claim 6, wherein N is greater than 1.

9. The method of claim 6, wherein the quantum dot material further comprises a plurality of quantum dots contained in a resin.

10. The method of claim 6, wherein the quantum dot material includes at least one quantum dot selected from the group consisting of ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, and combinations thereof.

11. The method of claim 1, further comprising the step of roughening or providing striations to a surface of the dispensed quantum dot material.

12. A method of making a sealed device, the method comprising:
providing a first substrate containing an array of wells;
dispensing quantum dot containing material into one or more wells of the array of wells;
hermetically sealing one or more wells in the array of wells; and
separating one or more wells from the array of wells to form a sealed device.

13. The method of claim 12, wherein the step of providing a first substrate containing an array of wells further comprises the step of etching the first substrate to form the array of wells.

14. The method of claim 12, wherein the step of dispensing quantum dot containing material further comprises:
(a) dispensing quantum dot material in a well using an ink jet;
(b) immobilizing the dispensed quantum dot material by drying or curing the dispensed quantum dot material; and
(c) repeating steps (a) and (b) an integer N number of times until a predetermined thickness is obtained.

15. The method of claim 14, wherein the ink jet is operated with an Ohnesorge (Oh) number between about 0.1 and about 1 and with a Weber number of between about 4 and about 50^{1.6}*Oh^{0.4}.

16. The method of claim 14, wherein N is greater than 1.

17. The method of claim 12, wherein the step of hermetically sealing further comprises:
bringing a first surface of a second substrate into contact with a second surface of the first substrate to form a sealing interface; and
directing a laser beam operating at a predetermined wavelength onto the sealing interface to form a seal between the first and second substrates.

18. The method of claim 12, wherein the quantum dot material further comprises a plurality of quantum dots contained in a resin.

19. The method of claim 12, wherein the quantum dot material includes at least one quantum dot selected from the group consisting of ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, and combinations thereof.

20. The method of claim 17, wherein the first, second, or both first and second substrates comprises a glass chosen from aluminosilicate, alkalialuminosilicate, borosilicate, alkali-borosilicate, aluminoborosilicate, and alkali-aluminoborosilicate glasses.

21. The method of claim 12, further comprising the steps of:
placing the sealed device over a third substrate, the third substrate comprising a third surface and having at least one cavity containing at least one LED component; and
sealing the sealed device to the third substrate to form another seal extending around the at least one cavity.

22. The method of claim 21, further comprising the step of providing one or more films to filter predetermined wavelengths of light, the one or more films comprising alternating films of high refractive index material and low refractive index material.
